(19) United States
(12) Patent Application Publication
(10) Pub. No.: US 2018/0083216 A1
(43) Pub. Date: Mar. 22, 2018

(54) ORGANIC ELECTROLUMINESCENT DEVICE AND DISPLAY APPARATUS

(71) Applicant: Shenzhen China Star Optoelectronics Technology Co., Ltd., Shenzhen, Guangdong (CN)

(72) Inventor: Kaifeng ZHOU, Shenzhen, Guangdong (CN)

(73) Assignee: Shenzhen China Star Optoelectronics Technology Co., Ltd., Shenzhen, Guangdong (CN)

(21) Appl. No.: 15/100,298

(22) PCT Filed: May 9, 2016
(86) PCT No.: PCT/CN2016/081461

§ 371 Date: May 28, 2016

(30) Foreign Application Priority Data
Apr. 5, 2016 (CN) 201610207450.7

(51) Int. Cl. H01L 51/50; H01L 51/52; H01L 27/32

(52) U.S. Cl. CPC H01L 51/504; H01L 51/5206; H01L 51/5088; H01L 27/3206; H01L 51/5072; H01L 51/5092; H01L 51/5221; H01L 51/5056

(57) ABSTRACT

This application discloses a display apparatus and an organic electroluminescent device, which includes a substrate; a first electrode, a first type carrier transporting and injection layer, a first light emitting layer, a heterojunction, a second light emitting layer, a second type carrier transporting and injection layer, a second electrode sequentially disposed on the same side of the substrate. the electrode provides a carrier, the carrier transporting and injection layer transport the carrier to the light emitting layer. The heterojunction generates exciton, and is separated into a first and a second type carrier. the first type carrier and the second type carrier are recombined in the first light emitting layer to generate a first light, the second type carrier and the first type carrier are recombined in the second light emitting layer to generate a second light, and the first light and the second light are mixed into a white light.

### CROSS REFERENCE

This application claims the priority of Chinese Patent Application No. 201610207450.7, entitled “ORGANIC ELECTROLUMINESCENT DEVICE AND DISPLAY APPARATUS”, filed on Apr. 5, 2016, the disclosure of which is incorporated herein by reference in its entirety.

### FIELD OF THE INVENTION

The present application relates to a display technology field, and more particularly to an organic electroluminescent device and display apparatus.

### BACKGROUND OF THE INVENTION

The organic electroluminescent devices such as organic light emitting diode, OLED with its own advantages, such as self-luminous, fast response, wide viewing angle, thin, low power consumption draws the industry's wildly attention. It has great meaning that the white organic light emitting diodes, WOLED can be as a light source and be used in lighting filed. The white organic light emitting diodes with a color filter can achieve the full color display be used in display filed. Currently WOLED is mainly formed through binary complementary colors or mixing three primary colors. The binary complementary color WOLED had mainly introduced a blue light-emitting layer and a yellow light emitting material layer stacking structure, the structure and the process is relatively simple. However, the color purity of the white light and the color rendering properties is low and since the carrier at each interface can not be effectively separated. It will be result as the injection and recombination of the carrier material in the blue light-emitting layer and the yellow light emitting material layer is imbalanced, and the current efficiency of the WOLED is lower and the driving voltage is high, leading to low power efficiency and high power consumption.

### SUMMARY OF THE INVENTION

The present application provides an organic electroluminescent device, including a substrate; a first electrode, a first type carrier transporting and injection layer, a first light emitting layer, a heterojunction, a second the light emitting layer, a second carrier transporting and injection layer and a second electrode sequentially disposed on the same side of the substrate; wherein the first electrode loads a first polarity voltage and provides a first type carrier, the first type carrier transporting and injection layer is used to transport the first type carrier to the first light emitting layer, the second electrode loads a second polarity voltage and provides a second type carrier, the second polarity voltage and the first polarity voltage form the first electrical field, the second carrier transporting and injection layer is used to transport the second type carrier to the second light emitting layer, a second electrical filed is formed inside the heterojunction, the direction of the first electric field and the second electric field are in the opposite direction, the heterojunction is used to generate exciton, and the exciton is separated into a first type carrier and a second type carrier under the function of the first electrical field, the first type carrier from the first electrode and the second type carrier from the heterojunction is recombined in the first light emitting layer to generate a first light, the second type carrier from the second electrode and the first type carrier from the heterojunction is recombined in the second light emitting layer to generate a second light, and the first light and the second light are mixed into a white light and is emitted according the direction of the substrate away from the first electrode.

Wherein the first electrode is an anode, the second electrode is a cathode, the first type carrier transporting and injection layer is a hole injection and transporting layer, the second type carrier transporting and injection layer is an electron injection and transporting layer, the first type carrier is a hole, and the second type carrier is an electron.

Wherein the first type carrier transporting and injection layer including a p-type doped semiconductor material, and the second type carrier transporting and injection layer including an n-type doped semiconductor material.

Wherein the heterojunction including an n-type semiconductor layer and a p-type semiconductor material layer laminate disposed, the n-type semiconductor material layer is disposed in one side of the first light emitting layer away from the first type carrier transporting and injection layer, the surface of the p-type semiconductor material layer remote from the n-type semiconductor material layer is disposed in one side of the second light emitting layer away from the second type carrier transporting and injection layer.

Wherein the first light emitting layer is a blue light emitting layer, the first light is a blue light, the second light emitting layer is a yellow layer emitting layer, the second light is a yellow light.

Wherein the first electrode is a cathode, the second electrode is an anode, the first type carrier transporting and injection layer is an electron injection and transporting layer, the second type carrier transporting and injection layer is an hole injection and transporting layer, the first type carrier is an electron, and the second type carrier is a hole.

Wherein the first type carrier transporting and injection layer including an n-type doped semiconductor material, and the second type carrier transporting and injection layer including a p-type doped semiconductor material.

Wherein the heterojunction including an n-type semiconductor layer and a p-type semiconductor material layer laminate disposed, the p-type semiconductor material layer is disposed in one side of the first light emitting layer away from the first type carrier transporting and injection layer, the surface of the n-type semiconductor material layer remote from the p-type semiconductor material layer is disposed in one side of the second light emitting layer away from the second type carrier transporting and injection layer.

Wherein the first electrode is a transparent electrode, the second electrode is metal electrode.

A display apparatus is also provided in the present application. The display apparatus includes the organic electroluminescent device according to the embodiments described in this application.

Comparing to the conventional technology, the first type carrier transporting and injection layer, the heterojunction and the second type carrier transporting and injection layer of the organic electroluminescent device form a P-I-N structure. The P-I-N structure can prevent the exciton quenching at the interface, balance the carrier concentration in the organic electroluminescent device, thereby increasing the current efficiency of the organic electroluminescent device and ultimately improve the power efficiency of the organic electroluminescent device. And the structure in the organic electroluminescent device can effectively reduce the driving voltage of the organic electroluminescent device, thereby reducing the power consumption of the organic electroluminescent device.

### BRIEF DESCRIPTION OF THE DRAWINGS

In order to more clearly illustrate the embodiments of the present application or prior art, the following figures will be described in the embodiments are briefly introduced. It is obvious that the drawings are merely some embodiments of the present application, those of ordinary skill in this field can obtain other figures according to these figures without paying the premise.

FIG. 1 illustrates a schematic cross-sectional structure of an organic electroluminescent device according to a preferred embodiment of the present application;

FIG. 2 illustrates the direction the an electric fields of the heterojunction and organic electroluminescent device according to a preferred embodiment of the present application;

FIG. 3 illustrates a schematic cross-sectional structure of an organic electroluminescent device according to another preferred embodiment of the present application; and

FIG. 4 illustrates a schematic structure of a display apparatus according to a preferred embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts obtained should be considered within the scope of protection of the present application.

Specifically, the terminologies in the embodiments of the present application are merely for describing the purpose of the certain embodiment, but not to limit the invention. Examples and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

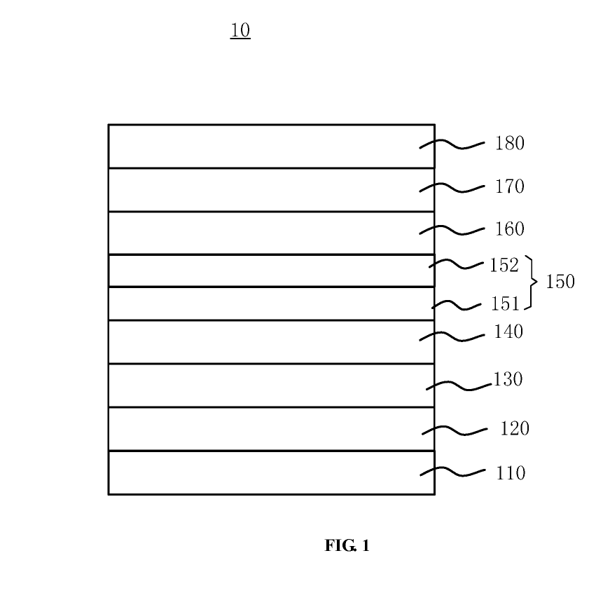

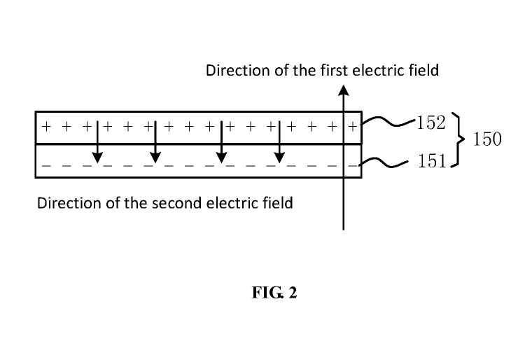

Refer to FIG. 1 and FIG. 2, FIG. 1 illustrates a schematic cross-sectional structure of an organic electroluminescent device according to a preferred embodiment of the present application. FIG. 2 illustrates the direction of the an electric fields of the heterojunction and organic electroluminescent device according to a preferred embodiment of the present application. The organic electroluminescent device 10 can be but not limited to the organic light emitting diode. The organic electroluminescent device 10 includes a substrate 110, a first electrode 120, a first type carrier transporting and injection layer 130, a first light emitting layer 140, a heterojunction 150, a second the light emitting layer 160, a second carrier transporting and injection layer 170 and a second electrode 180 sequentially disposed on the same side of the substrate 110. In this embodiment, the surface of the first electrode 120 is away from the first type carrier transporting and injection layer 130 is set on the substrate 110. The first electrode 120 loads a first polarity voltage and provides a first type carrier. The first type carrier transporting and injection layer 130 is used to transport the first type carrier to the first light emitting layer 140. The second electrode 180 loads a second polarity voltage and provides a second type carrier. The second polarity voltage and the first polarity voltage form the first electrical field. The second carrier transporting and injection layer 170 is used to transport the second type carrier to the second light emitting layer 160. A second electrical filed is formed inside the heterojunction 150, and the direction of the first electric field and the second electric field are in the opposite direction. The heterojunction 150 is used to generate exciton, and the exciton is separated into a first type carrier and a second type carrier under the function of the first electrical field. The first type carrier from the first electrode 120 and the second type carrier from the heterojunction 150 is recombined in the first light emitting layer 140 to generate a first light. The second type carrier from the second electrode 180 and the first type carrier from the heterojunction 150 is recombined in the second light emitting layer 160 to generate a second light. The first light and the second light is mixed into a white light and is emitted according the direction of the substrate 120 away from the first electrode 110. It can be understood that the second electric field is less than the first electric field.

The substrate 110 is a transparent substrate, the substrate 110 including but not limited to a glass substrate or a plastic substrate.

In one embodiment, the first electrode 120 is an anode, the second electrode 180 is a cathode, the first type carrier transporting and injection layer 130 is a hole injection and transporting layer, the second type carrier transporting and injection layer 170 is an electron injection and transporting layer, the first type carrier is a hole, and the second type carrier is an electron.

In the present embodiment, the first electrode 120 is a transparent electrode, the second electrode 180 is a metal electrode. Therefore, the first light and the second light mix into white light and is emitted according the direction of the substrate 120 away from the first electrode 110.

Preferably, the first type carrier transporting and injection layer 130 includes a p-type doped semiconductor material, and the second type carrier transporting and injection layer 170 includes an n-type doped semiconductor material.

In the present embodiment, the first light emitting layer 140 is a blue light emitting layer, respectively, the first light is a blue light, the second light emitting layer 160 is a yellow layer emitting layer, the second light is a yellow light and the blue light and the yellow light mixes into white light.

Specifically, after the exciton generated from the heterojunction 150 is separated into the first type carrier and the second type carrier, and under the function of the first electrical field, the first type carrier and the second type carrier in the heterojunction 150 move in the opposite direction. Specifically, under the function of the first electrical field, the first type carrier in the heterojunction 150 is transport to the second light emitting layer 160 and the second type carrier in the heterojunction 150 is transport to the first light emitting layer 140.

In the present embodiment, the heterojunction 150 includes an n-type semiconductor layer 151 and a p-type semiconductor material layer 152 laminate disposed. The n-type semiconductor material layer 151 is disposed in one side of the first light emitting layer 140 away from the first type carrier transporting and injection layer 130, the surface of the p-type semiconductor material layer 152 remote from the n-type semiconductor material layer 151 is disposed in one side of the second light emitting layer 160 away from the second type carrier transporting and injection layer 170.

In the present embodiment, the n-type semiconductor material layer 151 is formed of a host material and an n-type dopant. The host material is a high electron mobility material, the n-type dopant having a shallow LUMO level, and the n-type dopant and the host material are capable of forming a charge transfer. The p-type semiconductor material layer 152 is formed of a host material and a p-type dopant. The host material is a material having high hole mobility, the p-type dopant having a deeper HOMO level, the p-type dopant and the host material are capable of forming a charge transfer.

The first type carrier transporting and injection layer 130, the first light emitting layer 140 and n-type semiconductor material layer 151 of the heterojunction 150 constitute a light emitting unit. For the convenience of the description, the light emitting unit of the first type carrier transporting and injection layer 130, the first light emitting layer 140 and n-type semiconductor material layer 151 of the heterojunction 150 is referred as a first light emitting unit. The second type carrier transporting and injection layer 170, the second light emitting layer 160 and the p-type semiconductor material layer 152 of the heterojunction 150 constitute a light emitting unit. For the convenience of the description, the second type and injecting a carrier transport layer 170, the light emitting unit of the second type carrier transporting and injection layer 170, the second light emitting layer 160 and the p-type semiconductor material layer 152 of the heterojunction 150 is referred as a second light emitting unit.

In the present embodiment, the first type carrier transporting and injection layer 130, the heterojunction 150 and the second type carrier transporting and injection layer 170 of the organic electroluminescent device 10 forms a P-I-N structure. The P-I-N structure can prevent the exciton quenching at the interface, balance the carrier concentration in the organic electroluminescent device 10, thereby increasing the current efficiency of the organic electroluminescent device 10 and ultimately improve the power efficiency of the organic electroluminescent device 10. And the structure in the organic electroluminescent device 10 can effectively reduce the driving voltage of the organic electroluminescent device 10, thereby reducing the power consumption of the organic electroluminescent device 10.

Further, the first type carrier transporting and injection layer 130, the first light emitting layer 140 and n-type semiconductor material layer 151 of the heterojunction 150 of the organic electroluminescent device 10 form a P-I-N structure; and the p-type semiconductor material layer 152 of the heterojunction 150, the second light emitting layer 160 and the second type carrier transporting and injection layer 170 of the organic electroluminescent device 10 form a P-I-N structure. The light emitting units of the light-emitting organic electroluminescent device unit 10 in the present application are P-I-N structures, the carrier concentration in each of the light emitting is further balanced, the current efficiency of the organic electroluminescent device 10 is further increased and the power efficiency of the organic electroluminescent device 10 is further improved, the driving voltage of the organic electroluminescent device 10 is further reduced, and the power consumption of the organic electroluminescent device 10 is further reduced.

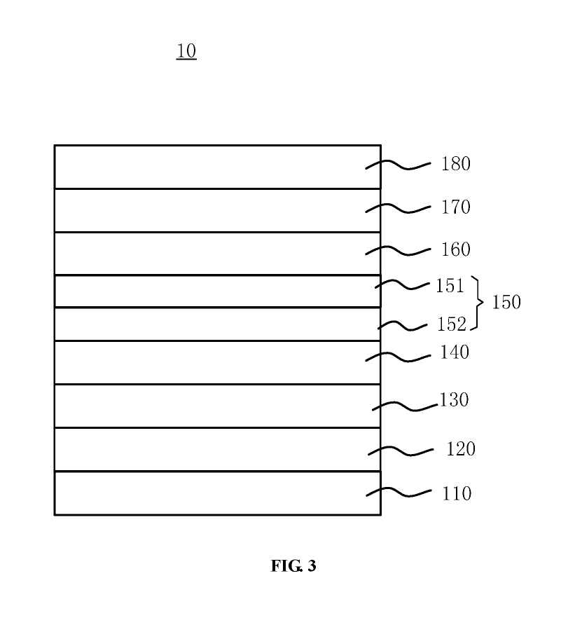

Refer to FIG. 3, FIG. 3 illustrates a schematic cross-sectional structure of an organic electroluminescent device according to another preferred embodiment of the present application. In this embodiment, the first electrode 120 is a cathode, the second electrode 180 is an anode, the first type carrier transporting and injection layer 130 is an electron injection and transporting layer, the second type carrier transporting and injection layer 170 is a hole injection and transporting layer. The first type carrier is electron and the second type carrier is hole.

Accordingly, the first type carrier transporting and injection layer 130 includes an n-type doped semiconductor material, said second type carrier transporting and injection layer 170 includes a p-type doped semiconductor material.

In the present embodiment, the heterojunction includes an n-type semiconductor layer 151 and a p-type semiconductor material layer 152 laminate disposed. The p-type semiconductor material layer 152 is disposed in one side of the first light emitting layer 140 away from the first type carrier transporting and injection layer 130, the surface of the n-type semiconductor material layer 151 remote from the p-type semiconductor material layer 152 is disposed in one side of the second light emitting layer 160 away from the second type carrier transporting and injection layer 170.

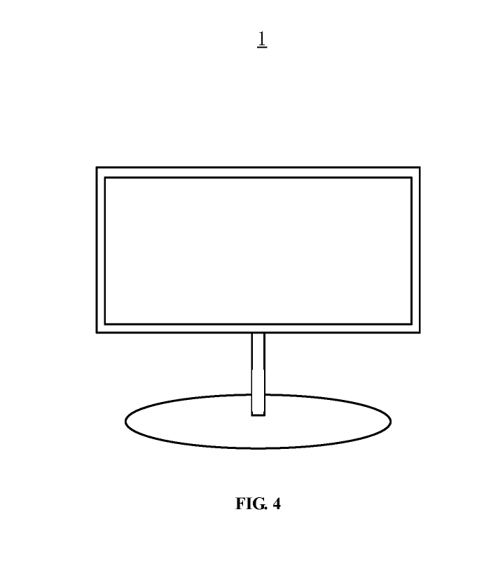

The present application also provides a display apparatus. Referring to FIG. 4, FIG. 4 illustrates a schematic structure of a display apparatus according to a preferred embodiment of the present application. The display apparatus 1 includes but are not limited to smart phones, Mobile Internet Device, MID, e-books, play station portable, PSP or a personal digital assistant, PDA and other portable electronic device can be a display or the like. The display apparatus 1 includes an organic electroluminescent device 10, the organic electroluminescent device 10 is as described above and are not discussed here.

Above are embodiments of the present application, which does not limit the scope of the present application. Any modifications, equivalent replacements or improvements within the spirit and principles of the embodiment described above should be covered by the protected scope of the invention.

What is claimed is:

1. An organic electroluminescent device, comprising
a substrate; a first electrode, a first type carrier transporting and injection layer, a first light emitting layer, a heterojunction, a second the light emitting layer, a second carrier transporting and injection layer and a second electrode sequentially disposed on the same side of the substrate; wherein the first electrode loads a first polarity voltage and provides a first type carrier, the first type carrier transporting and injection layer is used to transport the first type carrier to the first light emitting layer, the second electrode loads a second polarity voltage and provides a second type carrier, the second polarity voltage and the first polarity voltage form the first electrical field, the second carrier transporting and injection layer is used to transport the second type carrier to the second light emitting layer, a second electrical filed is formed inside the heterojunction, the direction of the first electric field and the second electric field are in the opposite direction, the heterojunction is used to generate exciton, and the exciton is separated into a first type carrier and a second type carrier under the function of the first electrical field, the first type carrier from the first electrode and the second type carrier from the heterojunction is recombined in the first light emitting layer to generate a first light, the second type carrier from the second electrode and the first type carrier from the heterojunction is recombined in the second light emitting layer to generate a second light, and the first light and the second light are mixed into a white light and is emitted according the direction of the substrate away from the first electrode.

2. The organic electroluminescent device according to claim 1, wherein the first electrode is an anode, the second electrode is a cathode, the first type carrier transporting and injection layer is a hole injection and transporting layer, the second type carrier transporting and injection layer is an electron injection and transporting layer, the first type carrier is a hole, and the second type carrier is an electron.

3. The organic electroluminescent device according to claim 2, wherein the first type carrier transporting and injection layer comprising a p-type doped semiconductor material, and the second type carrier transporting and injection layer comprising an n-type doped semiconductor material.

4. The organic electroluminescent device according to claim 3, wherein the heterojunction comprises an n-type semiconductor layer and a p-type semiconductor material layer laminate disposed, the n-type semiconductor material layer is disposed in one side of the first light emitting layer away from the first type carrier transporting and injection layer, the surface of the p-type semiconductor material layer remote from the n-type semiconductor material layer is disposed in one side of the second light emitting layer away from the second type carrier transporting and injection layer.

5. The organic electroluminescent device according to claim 3, wherein the first light emitting layer is a blue light emitting layer, the first light is a blue light, the second light emitting layer is a yellow layer emitting layer, the second light is a yellow light.

6. The organic electroluminescent device according to claim 2, wherein the first electrode is a cathode, the second electrode is an anode, the first type carrier transporting and injection layer is an electron injection and transporting layer, the second type carrier transporting and injection layer is an hole injection and transporting layer, the first type carrier is an electron, and the second type carrier is a hole.

7. The organic electroluminescent device according to claim 6, wherein the first type carrier transporting and injection layer comprising an n-type doped semiconductor material, and the second type carrier transporting and injection layer comprising a p-type doped semiconductor material.

8. The organic electroluminescent device according to claim 7, wherein the heterojunction comprises an n-type semiconductor layer and a p-type semiconductor material layer laminate disposed, the p-type semiconductor material layer is disposed in one side of the first light emitting layer away from the first type carrier transporting and injection layer, the surface of the n-type semiconductor material layer remote from the p-type semiconductor material layer is disposed in one side of the second light emitting layer away from the second type carrier transporting and injection layer.

9. The organic electroluminescent device according to claim 1, wherein the first electrode is a transparent electrode, the second electrode is metal electrode.

10. A display apparatus, wherein the display apparatus having an organic electroluminescent device, and the organic electroluminescent device comprising
a substrate; a first electrode, a first type carrier transporting and injection layer, a first light emitting layer, a heterojunction, a second the light emitting layer, a second carrier transporting and injection layer and a second electrode sequentially disposed on the same side of the substrate; wherein the first electrode loads a first polarity voltage and provides a first type carrier, the first type carrier transporting and injection layer is used to transport the first type carrier to the first light emitting layer, the second electrode loads a second polarity voltage and provides a second type carrier, the second polarity voltage and the first polarity voltage form the first electrical field, the second carrier transporting and injection layer is used to transport the second type carrier to the second light emitting layer, a second electrical filed is formed inside the heterojunction, the direction of the first electric field and the second electric field are in the opposite direction, the heterojunction is used to generate exciton, and the exciton is separated into a first type carrier and a second type carrier under the function of the first electrical field, the first type carrier from the first electrode and the second type carrier from the heterojunction is recombined in the first light emitting layer to generate a first light, the second type carrier from the second electrode and the first type carrier from the heterojunction is recombined in the second light emitting layer to generate a second light, and the first light and the second light are mixed into a white light and is emitted according the direction of the substrate away from the first electrode.

11. The display apparatus according to claim 10, wherein the first electrode is an anode, the second electrode is a cathode, the first type carrier transporting and injection layer is a hole injection and transporting layer, the second type carrier transporting and injection layer is an electron injection and transporting layer, the first type carrier is a hole, and the second type carrier is an electron.

12. The display apparatus according to claim 11, wherein the first type carrier transporting and injection layer comprising a p-type doped semiconductor material, and the second type carrier transporting and injection layer comprising an n-type doped semiconductor material.

13. The display apparatus according to claim 12, wherein the heterojunction comprises an n-type semiconductor layer and a p-type semiconductor material layer laminate disposed, the n-type semiconductor material layer is disposed in one side of the first light emitting layer away from the first type carrier transporting and injection layer, the surface of the p-type semiconductor material layer remote from the n-type semiconductor material layer is disposed in one side of the second light emitting layer away from the second type carrier transporting and injection layer.

14. The display apparatus according to claim 12, wherein the first light emitting layer is a blue light emitting layer, the first light is a blue light, the second light emitting layer is a yellow layer emitting layer, the second light is a yellow light.

15. The display apparatus according to claim 11, wherein the first electrode is a cathode, the second electrode is an anode, the first type carrier transporting and injection layer is an electron injection and transporting layer, the second type carrier transporting and injection layer is an hole injection and transporting layer, the first type carrier is an electron, and the second type carrier is a hole.

16. The display apparatus according to claim 15, wherein the first type carrier transporting and injection layer comprising an n-type doped semiconductor material, and the second type carrier transporting and injection layer comprising a p-type doped semiconductor material.

17. The display apparatus according to claim 16, wherein the heterojunction comprises an n-type semiconductor layer and a p-type semiconductor material layer laminate disposed, the p-type semiconductor material layer is disposed in one side of the first light emitting layer away from the first type carrier transporting and injection layer, the surface of the n-type semiconductor material layer remote from the p-type semiconductor material layer is disposed in one side of the second light emitting layer away from the second type carrier transporting and injection layer.

18. The display apparatus according to claim 10, wherein the first electrode is a transparent electrode, the second electrode is metal electrode.
